(19) United States
(12) Patent Application Publication
(10) Pub. No.: US 2016/0118769 A1
(43) Pub. Date: Apr. 28, 2016

(54) OPTICAL RESONATOR

(71) Applicant: MITUTOYO CORPORATION, Kanagawa (JP)

(72) Inventor: Tatsuya NARUMI, Kawasaki (JP)

(73) Assignee: MITUTOYO CORPORATION, Kanagawa (JP)

(21) Appl. No.: 14/887,463

(22) Filed: Oct. 20, 2015

(30) Foreign Application Priority Data
Oct. 24, 2014 (JP) 2014-216911

(51) Int. Cl. H01S 5/024; H01S 3/16; H01S 5/022; H01S 3/105; H01S 3/094

(52) U.S. Cl. CPC H01S 5/02446; H01S 3/105; H01S 3/094065; H01S 5/022; H01S 5/02415; H01S 3/1673; H01S 3/1611

(57) ABSTRACT

An optical resonator includes a casing and various optical elements (laser crystal, SHG, etalon, movable mirror) provided within the casing. The optical resonator causes light from the excited laser crystal to resonate and, using the etalon, emits single longitudinal mode laser light. The casing is formed with a low thermal expansion metal exhibiting a thermal expansion coefficient within a range of 0.1 to 3.0×10⁻⁶K⁻¹ and thermal conductivity within a range of 10 to 15 W·m⁻¹·K⁻¹. A first temperature control system controlling the temperature of the laser crystal and SHG to be a constant temperature is provided at a placement portion of the laser crystal and SHG. An angle adjuster adjusting an incident angle of the etalon and a second temperature control system controlling the temperature of the etalon to be a constant temperature are provided at a placement portion of the etalon.

### CROSS-REFERENCE TO RELATED APPLICATIONS

The present application claims priority under 35 U.S.C. §119 of Japanese Application No. 2014-216911, filed on Oct. 24, 2014, the disclosure of which is expressly incorporated by reference herein in its entirety.

### BACKGROUND OF THE INVENTION

1. Field of the Invention

The present invention relates to an optical resonator, and particularly relates to an optimized temperature control system of an optical element installed within the optical resonator.

2. Description of Related Art

Generally, in a laser apparatus of a type exciting a laser crystal with a semiconductor laser, an optical resonator is used which is configured by positioning optical elements such as the laser crystal and an etalon between a pair of reflecting surfaces. As described in Japanese Patent Laid-open Publication Nos. 2003-158316 and 2000-208849, a temperature control system in an optical resonator is necessary for efficiently stabilizing laser output.

A laser apparatus according to Japanese Patent Laid-open Publication No. 2003-158316 includes an automatic power control device controlling a predetermined emission of laser light so as to be emitted to an exterior by feeding output of a light detector for a monitor back to a drive circuit of a semiconductor laser. In addition, a temperature tuning control device is provided which reads a semiconductor laser drive current at a time when temperatures of a block (casing), semiconductor laser, and etalon have been individually changed by respective temperature control devices; calculates for each component the temperature at which the drive current is lowest; and defines each temperature as a defined temperature for a block temperature control device, semiconductor laser temperature control device, and etalon temperature control device, respectively. The temperature tuning control device operates in a state where the automatic power control device is running. As a result, Japanese Patent Laid-open Publication No. 2003-158316 describes compensating for time-related changes to each of the temperature sensors detecting the respective temperatures as well as mechanical or dimensional time-related changes to the block, for example, and stably performing efficient laser output.

Specifically, in the temperature tuning according to Japanese Patent Laid-open Publication No. 2003-158316, first, the temperature of the block is changed based on the temperature of a wavelength conversion element (SHG). Then, the temperature at which the drive current is lowest is found and the defined temperature of the block is updated to that temperature. As a result, time-related changes to the temperature sensor or the like are compensated for. In addition, the document describes utilizing temperature dependency of a refractive index of the SHG fixated to the block to change an optical path length within the SHG to compensate for dimensional changes to the block.

In addition, through temperature control of the etalon, peak transparent wavelength of the etalon is changed, the etalon temperature at which the drive current is lowest is found, and this temperature is set as the defined temperature of the etalon. In this example, the document describes that a case where the drive current is at its lowest is treated as a time when wavelength selection characteristics of the etalon match a design value, compensating for time-related changes to the temperature sensor or the like.

In a laser apparatus according to Japanese Patent Laid-open Publication No. 2000-208849, a temperature control device for an entire optical resonator and a temperature control device for an etalon are provided independently of each other; the entire optical resonator is kept at a constant temperature by the first temperature control device; and the temperature of the etalon is controlled by the second temperature control device such that a peak transparent wavelength of the etalon matches a peak emission wavelength of a laser emission. Specifically, a temperature definition value of the etalon is changed and a peak transparent wavelength position is shifted such that an emission laser light intensity is maximized. The temperature of the etalon being controlled independently, and the peak transparent wavelength of the etalon being matched to the peak emission wavelength of the laser emission are aspects shared with Japanese Patent Laid-open Publication No. 2003-158316.

However, the laser apparatus according to Japanese Patent Laid-open Publication No. 2003-158316 compensates for fluctuations in optical path length of the resonator, time-related changes to the temperature sensors, and the like by adjusting the temperature of optical elements, and every time the laser apparatus is powered on, temperature tuning is performed and the defined temperatures for the block and Peltier element are respectively updated. Therefore, as fluctuations in the optical path length and time-related changes advance, the difference between the defined temperature of the various elements and room temperature, for example, gradually increases and power consumption of the temperature control device (Peltier element or the like) needed to cancel out this difference also gradually increases, making effective and efficient laser output difficult. In addition, changing the temperature of the etalon to change the peak transparent wavelength using temperature tuning may cause instability in an emitted wavelength.

Similarly, in the laser apparatus according to Japanese Patent Laid-open Publication No. 2000-208849, the temperature control device for the etalon controls the temperature of the etalon such that the peak transparent wavelength of the etalon matches the peak emission wavelength of the laser emission. Therefore, instability of the emission wavelength is a concern.

### SUMMARY OF THE INVENTION

The present invention has been conceived in view of the related art and optimizes a temperature control system for various optical elements within an optical resonator in order to efficiently stabilize laser output and emitted wavelength.

The present invention provides an optical resonator that includes a casing, a pair of reflecting surfaces provided to the casing, a laser crystal positioned between the reflecting surfaces, and a wavelength selection element. The optical resonator causes light from the excited laser crystal to resonate between the reflecting surfaces and, using the wavelength selection element, emits single longitudinal mode laser light. The laser crystal includes a first temperature maintainer maintaining the laser crystal at a constant temperature. The wavelength selection element includes an angle adjuster adjusting an incident angle of laser light on the wavelength selection element; and a second temperature maintainer maintaining the wavelength selection element at a constant temperature independently of the first temperature maintainer. The casing is formed with a low thermal expansion metal exhibiting a thermal expansion coefficient within a range of 0.1 to 3.0×10⁻⁶(K⁻¹) and thermal conductivity within a range of 10 to 15 (W·m⁻¹·K⁻¹). At least one of the pair of reflecting surfaces is a movable mirror advancing and retreating along an optical path of the laser light. The casing includes a displacer positioning the movable mirror so as to obtain laser light of a desired wavelength.

In another aspect of the optical resonator, the angle adjuster includes a movable retention member capable of rotating around an axis provided to the casing, the movable retention member holding the wavelength selection element; and the second temperature maintainer is provided to the movable retention member.

In another aspect of the optical resonator, the first temperature maintainer is provided to the casing at a position closer to the laser crystal than the wavelength selection element, and the second temperature maintainer is provided to the casing at a position closer to the wavelength selection element than the laser crystal.

In the present invention, a defined temperature for each optical element is not updated in response to various conditions, but rather the temperature control system maintains each optical element at a constant temperature. In order to accomplish this, first, the casing used is made of a low thermal expansion metal. Accordingly, fluctuations in optical path length due to thermal expansion of the casing can be inhibited and a reduction in laser output or the like can be avoided. Next, the angle adjuster is provided for the wavelength selection element, enabling the incident angle to be adjusted so as to enable the element to select the desired wavelength in a constant temperature. Through this angle adjustment, variation in wavelength selection characteristics between products due to machining accuracy or the like can be negated.

Moreover, the two temperature maintainers maintain each optical element at the defined temperature, and therefore optical fluctuations in the optical path length due to thermal expansion of the various optical elements can be inhibited. Changes in peak transparent wavelength accompanying changes in temperature can also be inhibited for the wavelength selection element.

By providing the low thermal expansion metal casing, the angle adjuster for the wavelength selection element, and the two temperature maintainers, the peak transparent wavelength of the wavelength selection element matches an emission wavelength based on the optical path length of the optical resonator, and therefore a reduction in laser output and fluctuation in emitted wavelength can be avoided without changing the defined temperature for each optical element.

In addition to the above-described system, by changing the position of the movable mirror using the movable mirror and the displacer, extremely minor optical changes in optical path length caused by fluctuations in a refractive index of air or the like are negated, and therefore fluctuations in laser output and emitted wavelength can be stabilized at a higher level.

By employing the temperature control system having the above-described configuration, deleterious effects due to using the low thermal expansion metal casing can be avoided. Each of the optical elements is supported directly or indirectly on the casing, and therefore the thermal energy of each optical element is likely to transfer to the casing. Similarly, the thermal energy of the casing is likely to transfer to each of the optical elements. The low thermal expansion metal used for the casing generally has low thermal conductivity as compared to other metals and heat is likely to be retained in various portions of the casing. Therefore, even when attempting to control the temperature for an entire casing (block) so as to be uniform, at portions close to the various optical elements, transfer of thermal energy with those elements becomes predominant and heat is unlikely to spread through the entire casing. Therefore, non-uniformities arise in the temperature of the casing. As a result, in a system controlling the temperature for the entire casing so as to be uniform, the temperature of individual optical elements is likely to become unstable due to temperature irregularities in the casing, and stabilization of the emitted laser may be affected. In contrast, in the present invention, two temperature maintainers respectively control the temperature of specific optical elements directly. Therefore, the present invention is unlikely to suffer effects due to non-uniformity in the temperature of the casing and temperature control of the various optical elements is stabilized.

Due to the configuration that provides the low thermal expansion metal casing, the angle adjuster for the wavelength selection element, the two temperature maintainers, the movable mirror, and the displacer, as noted above, when the optical resonator is used, simply by executing a movement to position the movable mirror to obtain laser light having the desired wavelength, stable laser output as well as the desired emitted wavelength can be obtained efficiently and with a high degree of accuracy.

In addition, in the present invention, in a case where the wavelength selection element is attached to the movable support member, and the incident angle is adjusted by adjusting an inclination of the movable support member, the second temperature maintainer is provided to the movable support member and the temperature of the wavelength selection element is controlled via the movable support member. In this way, even when the second temperature maintainer is not provided directly to the wavelength selection element, the temperature of the wavelength selection element is stabilized by temperature control in the portion proximate to the wavelength selection element.

In addition, in a case where the temperature maintainer is provided to the casing, the temperature maintainer is provided at a portion of the casing as close as possible to the optical element to be controlled. Even when non-uniformity in the temperature of the casing occurs, by performing temperature control at the portion proximate to each optical element, the temperatures of the optical elements are stabilized.

### BRIEF DESCRIPTION OF THE DRAWINGS

The present invention is further described in the detailed description which follows, in reference to the noted plurality of drawings by way of non-limiting examples of exemplary embodiments of the present invention, in which like reference numerals represent similar parts throughout the several views of the drawings, and wherein:

FIG. 1 is a front view illustrating, in partial cross-section, an overall configuration of an optical resonator according to a first embodiment of the present invention;

FIG. 2 is a front view illustrating, in partial cross-section, an overall configuration of an optical resonator according to a second embodiment of the present invention; and

FIG. 3 is a plan view illustrating an overall configuration of a laser device using the optical resonator according to the present invention.

### DETAILED DESCRIPTION OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in the art how the forms of the present invention may be embodied in practice.

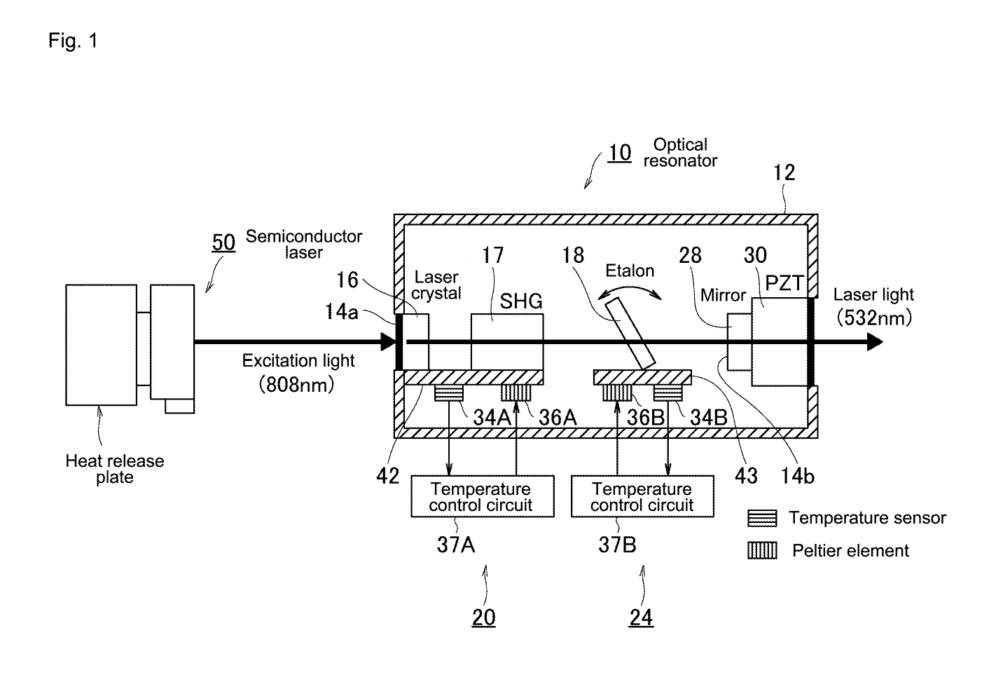

Hereafter, preferred embodiments of the present invention are described with reference to the drawings. FIG. 1 illustrates an overall configuration of an optical resonator according to a first embodiment of the present invention. In FIG. 1, an optical resonator 10 receives excitation light from a semiconductor laser 50 provided to an exterior of the optical resonator 10; generates laser light on an interior of the optical resonator 10; and, after going through various processes such as amplification, harmonic wave conversion, and wavelength selection, emits laser light having a desired wavelength (for example, 532 nm) from an emission aperture.

Specifically, the optical resonator 10 includes a casing 12; a laser crystal 16 excited by excitation light to emit light; a second harmonic generation element (SHG) 17; an etalon 18 as a wavelength selection element (wavelength selector); a movable mirror 28 as the laser light emission aperture; and a piezoelectric element 30 as a movable mirror 28 displacer. The optical resonator 10 further includes an angle adjustment mechanism for the etalon 18 and two temperature control systems 20 and 24.

The laser crystal (for example, Nd:YVO₄) is arranged in the casing 12 as a firing aperture for the excitation light, and a pair of reflecting surfaces 14a and 14b according to the present invention are formed by an outer surface of the laser crystal 16, through which the excitation light is fired, and a reflecting surface of the movable mirror 28, which is a half mirror. The optical resonator 10 causes the light issued from the excited laser crystal 16 to resonate between the reflecting surfaces and emits laser light having a wavelength (1064 nm) corresponding to a length of an optical path between the reflecting surfaces (in other words, a resonator length).

In addition, the SHG 17 positioned within the casing converts the laser light into a second harmonic wave (532 nm), and therefore two kinds of laser light having wavelengths of 1064 nm and 532 nm, respectively, are emitted through the movable mirror 28. A nonlinear optical crystal of KTiOPO₄ (KTP) or the like may be used as the SHG. By arranging the SHG between the reflecting surfaces, visible laser light (such as green laser light) can be emitted. Of course, there is no need to provide an SHG to an optical resonator supplying infrared laser light (1064 nm).

The etalon 18 may serve as a wavelength filter through which a specific wavelength is intensified as it passes. In a case where the etalon 18 is not used, multilongitudinal mode laser light is emitted. Light from the laser crystal 16 exhibits a spectral distribution with a natural width, and by amplifying a wavelength therein that matches the resonant frequency of the optical resonator 10, laser light is generated having a plurality of peak frequencies. By arranging the etalon on the optical path, only the desired laser light having the resonant frequency is transmitted and a single longitudinal mode laser light is emitted.

A temperature control system according to the present invention is described in detail below. The temperature control system according to the present embodiment is configured by the following five components:

(1) Casing formed of low thermal expansion metal;
(2) First temperature control system keeping a laser crystal and SHG at a constant temperature;
(3) Angle adjustment mechanism adjusting incidence angle of laser light on an etalon;
(4) Second temperature control system keeping the etalon at a constant temperature, independently of the first temperature control system; and
(5) Wavelength control system using a movable mirror.

(1) Casing Material

Material for the casing 12 is a low thermal expansion metal exhibiting a thermal expansion coefficient within a range of 0.1 to 3.0×10⁻⁶ (K⁻¹) and a thermal conductivity of 10 to 15 (W·m⁻¹·K⁻¹) or less. In particular, the nickel alloy Invar (Fe64-Ni36) is readily available and easy to handle. In general, thermal characteristics of Invar are as follows:

Average thermal expansion coefficient (room temperature to 100° C.): 0.5 to 2.0×10⁻⁶ (K⁻¹)
Thermal conductivity (23° C.): 13 to 14 (W·m⁻¹·K⁻¹)

(2) Constant Temperature Control of Laser Crystal and SHG

The first temperature control system 20 corresponds to a first temperature maintainer according to the present invention, and includes a temperature sensor 34A, a Peltier element 36A (heat transfer element), and a temperature control circuit 37A. As shown in FIG. 1, the laser crystal 16 and SHG 17 are fixated to a placement portion 42 formed integrally with the casing 12, and the temperature sensor 34A and Peltier element 36A are mounted to the same placement portion 42. By detecting a temperature of the placement portion 42, the temperature sensor 34A obtains the temperature of the laser crystal 16 and SHG 17. A temperature control circuit 37A performs drive control of the Peltier element 36A in accordance with a difference between a defined temperature and a detected temperature. The Peltier element 36A absorbs and releases heat from the placement portion 42 and maintains the temperature of the various optical elements at the defined temperature. Through such constant temperature control, optical fluctuations in optical path difference of the laser crystal 16 and SHG 17 can be inhibited.

(3) Incident Angle Adjustment for Etalon

The etalon 18 is supported so as to be capable of changing orientation using an angle adjustment mechanism (not shown in the drawings), and of adjusting an incident angle of the laser light. The etalon 18 exhibits variation in peak transparent wavelength among different products, which is caused by machining error. However, by adjusting the incident angle using the angle adjustment mechanism, desired peak transparent wavelength characteristics can be obtained regardless of what product is used, improving a yield rate of the etalon. Moreover, when the temperature of the etalon 18 is kept constant, fluctuations in the peak transparent wavelength are inhibited, and the peak transparent wavelength characteristics which were adjusted in the initial stage can be continuously achieved. Therefore, typically, angle adjustment of the etalon 18 may be performed during the initial adjustment during manufacturing, and there is no need to perform readjustment for each use. The angle adjustment mechanism is fixated to a placement portion 43, which is formed integrally with the casing 12.

(4) Constant Temperature Control of Etalon

The second temperature control system 24 has a configuration similar to that of the first temperature control system. However, a temperature sensor 34B and Peltier element 36B are mounted to the etalon placement portion 43. By detecting the temperature of the placement portion 43, the temperature sensor 34B obtains the temperature of the etalon 18. A temperature control circuit 37B performs drive control of the Peltier element 36B in accordance with a difference between a defined temperature and a detected temperature. The Peltier element 36B absorbs and releases heat from the placement portion 43 and maintains the temperature of the etalon 18 at the defined temperature. The defined temperature of the etalon 18 is set to the same temperature as the defined temperature of the laser crystal 16 and SHG 17. Through such constant temperature control, not only can optical fluctuations in optical path difference of the etalon 18 be inhibited, but in addition the peak transparent wavelength of the etalon 18 does not fluctuate.

(5) Wavelength Control Using Movable Mirror

An optical path length between the pair of reflecting surfaces 14a and 14b can be said to not fluctuate for the most part due to the casing 12 being formed of a low thermal expansion metal. However, although slight, changes in dimension are likely to occur over time. In addition, when the temperatures of the various optical elements (laser crystal 16, SHG 17, etalon 18, and the like) within the casing 12 are controlled so as to be constant, changes in dimension due to thermal expansion of the various optical elements can also be said to be extremely rare. However, the characteristics of the various optical elements, for example, may change over time. Even when such time-related changes do not occur, when a fluctuation in pressure of air within the casing (atmospheric pressure) occurs, a refractive index of the air changes, changing the optical path length of the optical resonator 10, and laser light of a desired wavelength can no longer be obtained.

In order to avoid effects from fluctuation in the refractive index of the air or from changes over time, in the present embodiment, the movable mirror 28 is capable of advancing and retreating along the optical path using the piezoelectric element 30 (such as a PZT), and the distance between the reflecting surfaces can be adjusted. As shown in FIG. 1, the piezoelectric element is provided to the casing 12 and, together with a piezoelectric drive control circuit (not pictured in the drawings), configures a displacer according to the present invention. A method of adjusting a position of the movable mirror 28 may provide an emitted laser wavelength detector (not shown) to the exterior of the optical resonator 10 and displace the movable mirror 28 such that a detected wavelength value matches the desired wavelength. In addition, the movable mirror 28 may also be placed at a position where intensity of the emitted laser is greatest. When an absorption line detector using an iodine cell or the like, described hereafter, is employed as the wavelength detector, the optical resonator 10 according to the present embodiment can be applied to a frequency stabilizing laser device in which fluctuation of the emitted wavelength is kept to a level of 1×10⁻⁸ or less. In particular, when absorption lines of iodine molecules are detected with a greater degree of accuracy due to adding a modulation ability to the movable mirror 28 using the piezoelectric element and modulating the wavelength of the emitted laser, the optical resonator 10 can be applied to a high-level frequency stabilizing laser device in which wavelength fluctuation is kept to a level of 1×10⁻¹° or less.

### Effect of the Embodiment

In the present embodiment, the above-described temperature control system is provided, and therefore deleterious effects due to using the low thermal expansion metal casing 12 can be avoided. In general, low thermal expansion metal has low thermal conductivity as compared to other metals and heat is likely to be retained in various portions of the casing 12. Therefore, when attempting to control the temperature for an entire casing in the conventional art so as to be uniform, for example, at portions close to optical elements such as the laser crystal 16 and the etalon 18, transfer of heat energy with those elements becomes predominant, heat is unlikely to spread through the entire casing, and non-uniformities arise in the temperature of the casing 12. In particular, in a case where a difference is established between the defined temperature of the casing 12 and the defined temperature of the individual optical elements such as the etalon 18, non-uniformities in the temperature of the casing 12 become striking. As a result, even when attempting to control the temperature for the entire casing so as to be uniform, the temperature of individual optical elements is likely to become unstable due to temperature irregularities in the casing 12, and stabilization of the emitted laser may be affected. In contrast, in the present embodiment, the first temperature control system 20 performs direct temperature control of the laser crystal 16 and SHG 17, and the second temperature control system 24 performs direct temperature control of the etalon 18. Accordingly, the present embodiment has made effects due to non-uniformity in the temperature of the casing 12 unlikely. As a result, temperature control of the various optical elements is stable, and therefore when the optical resonator 10 is used, simply by initially executing a movement to position the movable mirror 28 to achieve the desired wavelength, stable laser output as well as the desired emitted wavelength can be obtained efficiently and with a high degree of accuracy.

### Second Embodiment

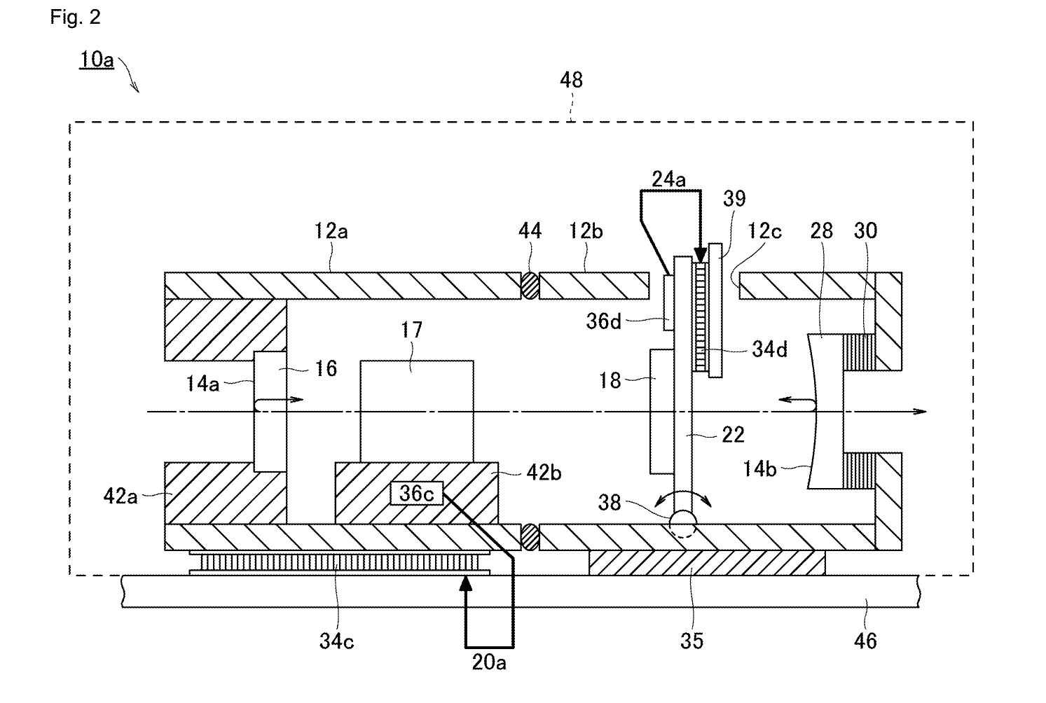

FIG. 2 illustrates an overall configuration of an optical resonator according to a second embodiment of the present invention. An optical resonator 10a has the low thermal expansion metal casing 12 formed in a squared tube shape, and has various optical elements arranged on an interior of the casing 12. The casing 12 is divided into two members 12a and 12b. The first half member 12a is positioned on a base 46 with a Peltier element 34c interposed between the member 12a and the base 46. The second half member 12b is positioned on the base 46 with a spacer 35 interposed between the member 12b and the base 46. A gap is provided between the two members 12a and 12b, and a thermal buffer material 44 is sealed in the gap. The optical resonator on the base 46 is covered by a cover 48.

The laser crystal 16 is fixated to the casing member 12a via a holder 42a. The SHG is also fixated to the casing member 12a via a separate holder 42b. An IC temperature sensor 36c is attached to the SHG holder 42b and, together with the Peltier element 34c positioned directly below the laser crystal 16 and SHG 17, configures a first temperature control system 20a according to the present embodiment. The defined temperature of the first temperature control system 20a is 25° C. (room temperature), and the laser crystal 16 and SHG 17 are subjected to constant temperature control such that the detected temperatures are in a range of 25° C.±0.1° C. The IC temperature sensor 36c may also be attached to the laser crystal holder 42a, rather than to the SHG holder 42b.

The etalon 18 is held by a swing plate 22 as a movable retention member (movable retainer). A base end of the swing plate 22 is provided so as to be capable of rotating around an axis 38 provided below the second half member 12b. An opening 12c is provided to the member 12b at a position facing the axis 38, a forefront end of the swing plate 22 extends up to the opening 12c, and heat transfer occurs between the etalon 18 and the casing exterior. In other words, a Peltier element 34d is attached near the forefront end of the swing plate 22, and absorbs and releases heat via a heat release plate 39 or the like. An IC temperature sensor 36d is also attached to the forefront end of the swing plate 22 and, together with the Peltier element 34d, configures a second temperature control system 24a according to the present embodiment. The defined temperature of the second temperature control system 24a is 25° C. (room temperature), and the etalon 18 is subjected to constant temperature control such that the detected temperature is in a range of 25° C.±0.1° C.

In a case where the etalon 18 is attached to the swing plate 22 and the incident angle is adjusted by changing an inclination of the swing plate 22 as in the present embodiment, the IC temperature sensor 36d and Peltier element 34d are provided to the swing plate 22 and the temperature of the etalon 18 is controlled via the swing plate 22. In this way, even in a case where no sensor or Peltier element is directly attached to the etalon 18, stabilizing the temperature of the etalon 18 can be facilitated by temperature control at a portion proximate to the etalon 18.

Modifications

The present embodiment uses the casings 12a and 12b, which have been split into two members; however, the casing 12 is not necessarily split into two members, and instead a shared casing 12 may be used. In addition, the Peltier element 34d of the second temperature control system 24a is not limited to being provided to the swing plate 22 for the etalon 18. For example, instead of the spacer 35, a Peltier element may be provided at the position of the spacer 35 on the base 46 as shown in FIG. 2, and the etalon 18 may be subjected to constant temperature control via the casing 12. In this modification, in the shared casing 12, the first temperature control system 20a is provided at a position comparatively close to the laser crystal 16 and SHG 17, and the second temperature control system 24a is provided at a position comparatively close to the etalon 18. In this way, in a case where a Peltier element is provided to the shared casing 12 for each temperature control system, a Peltier element is provided at a portion of the casing 12 as close as possible to the optical element to be controlled. Even when non-uniformity in the temperature of the casing 12 occurs, by performing temperature control at a portion proximate to each optical element, the temperatures of the optical elements can be more readily stabilized.

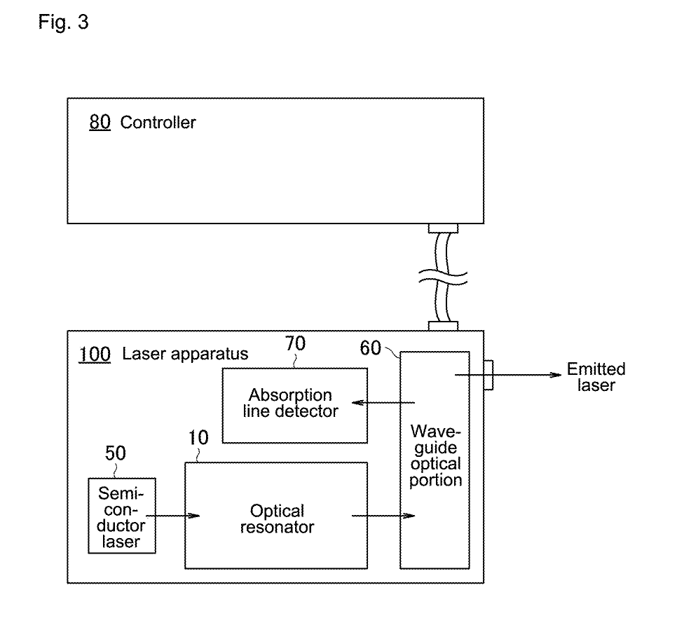

The optical resonator according to any of the embodiments is applied to a primary device of a laser apparatus 100, as shown in FIG. 3. The laser apparatus 100 includes a semiconductor laser 50, the optical resonator 10, a waveguide optical portion 60, and an absorption line detector 70. With the absorption line detector 70, which uses an iodine cell, the wavelength of the emitted laser is detected with a high degree of accuracy, and the movable mirror 28 of the optical resonator 10 is positioned such that the detected wavelength matches the desired wavelength. Although the absorption line detector 70 is described as a module independent of the optical resonator 10, the absorption line detector 70 is exemplary of the wavelength detector according to the optical resonator of the present invention.

It is noted that the foregoing examples have been provided merely for the purpose of explanation and are in no way to be construed as limiting of the present invention. While the present invention has been described with reference to exemplary embodiments, it is understood that the words which have been used herein are words of description and illustration, rather than words of limitation. Changes may be made, within the purview of the appended claims, as presently stated and as amended, without departing from the scope and spirit of the present invention in its aspects. Although the present invention has been described herein with reference to particular structures, materials and embodiments, the present invention is not intended to be limited to the particulars disclosed herein; rather, the present invention extends to all functionally equivalent structures, methods and uses, such as are within the scope of the appended claims.

The present invention is not limited to the above described embodiments, and various variations and modifications may be possible without departing from the scope of the present invention.

What is claimed is:

1. An optical resonator comprising:
a casing comprising a low thermal expansion metal exhibiting a thermal expansion coefficient within a range of 0.1 to 3.0×10⁻⁶(K⁻¹) and thermal conductivity within a range of 10 to 15 (W·m⁻¹·K⁻¹);
a pair of reflecting surfaces provided to the casing, wherein at least one of the pair of reflecting surfaces is a movable mirror advancing and retreating along an optical path of laser light;
a laser crystal positioned between the pair of reflecting surfaces, the laser crystal comprising a first temperature maintainer configured to maintain the laser crystal at a constant temperature; and
a wavelength selector comprising an angle adjuster configured to adjust an incident angle of the laser light on the wavelength selector and a second temperature maintainer configured to maintain the wavelength selector at a constant temperature independently of the first temperature maintainer, wherein:
light from the excited laser crystal is configured to resonate between the reflecting surfaces;
the wavelength selector is configured to emit single longitudinal mode laser light; and
the casing further comprises a displacer configured to position the movable mirror so as to obtain laser light of a predetermined wavelength.

2. The optical resonator according to claim 1, wherein:
the angle adjuster includes a movable retainer configured to rotate about an axis provided to the casing, the movable retainer holding the wavelength selector, and
the second temperature maintainer is provided to the movable retainer.

3. The optical resonator according to claim 1, wherein:
the first temperature maintainer is provided to the casing at a position closer to the laser crystal than the wavelength selector, and
the second temperature maintainer is provided to the casing at a position closer to the wavelength selector than the laser crystal.
